(19) United States
(12) Patent Application Publication
(10) Pub. No.: US 2010/0247274 A1
(43) Pub. Date: Sep. 30, 2010

(54) SUBSTRATE EXCHANGING MECHANISM AND METHOD OF EXCHANGING SUBSTRATES

(75) Inventor: YOJI IIZUKA, Nirasaki-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/729,286

(22) Filed: Mar. 23, 2010

(30) Foreign Application Priority Data
Mar. 24, 2009 (JP) 2009-072116

(51) Int. Cl. H01L 21/677

(52) U.S. Cl. 414/217; 414/805

(57) ABSTRACT

A substrate exchange mechanism and method is disclosed in which a first transferring member that has been moved into the load lock chamber is moved in a first direction of upward and downward directions, thereby transferring the first substrate between the first transferring member and the first supporting member; a second transferring member that has been moved into the load lock chamber is moved in the first direction; and a second supporting member of the load lock chamber in the first direction in at least an overlapping period of time with the second transferring member so that vertical positions of the second supporting member and the second transferring member are reversed, thereby transferring the second substrate between the second transferring member and the second supporting member.

### CROSS-REFERENCE TO RELATED APPLICATION

This application claims the benefit of priority of Japanese Patent Application No. 2009-072116, filed on Mar. 24, 2009 with the Japanese Patent Office, the entire contents of which are hereby incorporated by reference.

### BACKGROUND OF THE INVENTION

1. Field of the Invention

The present invention relates to a substrate exchanging mechanism that exchanges a processed substrate and an unprocessed substrate between an inside and an outside of a substrate processing apparatus, specifically to a substrate exchanging mechanism that exchanges substrates in a load lock chamber in the substrate processing apparatus, employing a transfer apparatus of the substrate processing apparatus.

2. Description of the Related Art

In a semiconductor fabrication process, substrates to be processed such as semiconductor wafers (referred to as simply wafers) are subject to various processes such as film deposition, etching, and the like carried out under vacuum. In recent years, a cluster tool including plural process chambers coupled with one another through a vacuum transfer chamber, where the wafer is transferred from one process chamber to another, has been attracting attention, from a viewpoint of efficient processing and contamination prevention (see Patent Document 1, for example).

Generally, such a cluster tool processing apparatus is provided with a load lock chamber between the vacuum transfer chamber and a wafer cassette station that is arranged in an atmospheric environment. The load lock chamber allows the wafer stored in a wafer cassette to be transferred into the vacuum transfer chamber while being kept under vacuum.

The wafer is transferred to/from the load lock chamber from/to the vacuum transfer chamber by a substrate exchanging mechanism provided in the vacuum transfer chamber. A conventional substrate exchanging mechanism has a transfer arm that is pivotable in a minimum necessary space and extendable in order to transfer the wafer a long way. The transfer arm is provided with plural pairs of rotation shafts and arms provided in tiers from a base of the transfer apparatus. On a distal end of the arm, there are provided a distal arm having two transfer members (forks) in corresponding ends of the distal arm in order to transfer the wafer (see Patent Document 2, for example).

Wafer transferring to/from the load lock chamber from/to the vacuum transfer chamber employing the substrate exchanging mechanism is carried out through two extension/contraction operations of the transfer arm. First, one of the transfer members (forks) that carries no wafer is moved into the load lock chamber, takes a wafer from a supporting member in the load lock chamber, and is moved out from the load lock chamber, which is the first extension/contraction of the transfer arm. Second, the transfer members are horizontally rotated so that the other one of the transfer members (forks) carrying a processed wafer is directed toward the load lock chamber. Then, the other one of the transfer members (forks) with the processed wafer is moved into the load lock chamber, places the process wafer on the supporting member in the load lock chamber, and is moved out from the load lock chamber, which is the second extension/contraction of the transfer arm.

In addition, a substrate exchanging mechanism that enables simultaneous exchange of two substrates between the load lock chamber and the transfer apparatus is disclosed in Patent Document 3. This substrate exchanging mechanism includes an upper stationary supporting member and a lower vertically movable supporting member that are provided in the load lock chamber, and a vertically movable transferring member having two supporting parts that is provided in the transfer apparatus. According to this substrate exchanging mechanism, first, a first substrate is supported by the upper stationary supporting member in the load lock chamber, and a second substrate is placed in a lower supporting part of the vertically movable transferring member of the transfer mechanism. Next, the vertically movable transferring member of the transfer apparatus is moved into the load lock chamber, so that the second wafer placed on the lower supporting part of the vertically movable transferring member is positioned above the vertically movable supporting member of the load lock chamber, and the upper supporting part of the vertically movable transferring member is positioned below the stationary supporting member of the load lock chamber. Then, the lower vertically movable supporting member is moved in a vertically opposite direction in relation to the lower supporting part of the vertically movable transferring member of the transfer apparatus, and then the upper supporting part of the vertically movable transferring member is moved in a vertically opposite direction in relation to the upper stationary supporting member.

Patent Document 1: Japanese Patent Application Laid-Open Publication No. 2000-208589.

Patent Document 2: Japanese Patent Application Laid-Open Publication No. H07-142551.

Patent Document 3: Japanese Patent Application Laid-Open Publication No. H09-223727.

However, there is the following problem when exchanging substrates between the load lock chamber and the transfer apparatus using the substrate exchanging mechanism.

When the substrate exchanging mechanism having two transferring members (forks) on both ends of a distal arm of the transfer apparatus as disclosed in Patent Document 2 is used, the distal arm needs to expand and contract twice in order to exchange a processed substrate and an unprocessed substrate, which increases a time required for exchanging the substrates.

Along with a further size decreasing design rule of semiconductor devices, a thickness of a film deposited on a semiconductor wafer to constitute the semiconductor devices is decreasing. In this case, a process time is becoming shorter in both depositing the film and etching the film. As a result, a time period required for exchanging substrates between the process chamber and the transfer chamber is becoming longer with respect to a deposition time and an etching time. Therefore, a substrate exchange time is desired to be shorter in order to increase throughput.

In addition, when a substrate exchanging mechanism disclosed in Patent Document 3 is used, two stationary substrate supporting members stacked one above the other need to be provided in addition to a movable substrate supporting member that can move the substrate upward/downward in the load lock chamber, which increases the number of parts in the load lock chamber and makes the load lock chamber complicated.

The present invention has been made in view of the above and provides a substrate exchanging mechanism that is configured into simple configurations and capable of increasing throughput.

### SUMMARY OF THE INVENTION

A first aspect of the present invention provides a substrate exchanging mechanism that exchanges substrates between a load lock chamber and a transfer apparatus of a substrate process apparatus. The substrate exchanging mechanism includes a first supporting member fixedly provided in the load lock chamber and configured to be capable of supporting a first substrate; a second supporting member, capable of vertical movement, in the load lock chamber and configured to be capable of supporting a second substrate; and a first transferring member and a second transferring member that are provided in the transfer apparatus in order to transfer a substrate, and configured to be movable into the load lock chamber and vertically movable, wherein the first supporting member and the first transferring member are configured so that the first transferring member is moved in a first direction of upward and downward directions in the load lock chamber, thereby transferring the first substrate between the first supporting member and the first transferring member, and wherein the second supporting member and the second transferring member are configured to move in the first direction in at least an overlapping period of time so that vertical positions of the first supporting member and the first transferring member are reversed, thereby transferring the second substrate between the first supporting member and the first transferring member.

A second aspect of the present invention provides a substrate exchange method carried out with a substrate exchanging mechanism according to the first aspect. The substrate exchange method includes steps of: moving the first transferring member that has been moved into the load lock chamber in the first direction of upward and downward directions, thereby transferring the first substrate between the first transferring member and the first supporting member; moving the second transferring member that has been moved into the load lock chamber in the first direction; and moving the second supporting member in the first direction in at least the overlapping period of time with the second transferring member so that vertical positions of the second supporting member and the second transferring member are reversed, thereby transferring the second substrate between the second transferring member and the second supporting member.

### BRIEF DESCRIPTION OF THE DRAWINGS

FIG. 1 is a plan view of a substrate process apparatus provided with a substrate exchanging mechanism according to an embodiment of the present invention.

FIG. 2 is a perspective view of the substrate exchange apparatus according to the embodiment of the present invention.

FIG. 3 is a perspective view of first and second transferring members of the substrate exchange apparatus.

FIG. 4 is an explanatory view for explaining a substrate exchange method according to an embodiment of the present invention.

FIG. 5 is a modified example of the substrate exchange method illustrated in FIG. 4.

FIG. 6 is another modified example of the substrate exchange method illustrated in FIG. 4.

FIG. 7 is an explanatory view for explaining a substrate exchange method according to another embodiment of the present invention.

FIG. 8 is an explanatory view for explaining effects (or advantages) of the substrate exchanging mechanism and methods according to the embodiments of the present invention.

FIG. 9 is an explanatory view for explaining a substrate exchange method according to yet another embodiment of the present invention.

FIG. 10 is a modified example of the substrate exchange method illustrated in FIG. 9.

FIG. 11 is another modified example of the substrate exchange method illustrated in FIG. 9.

### DETAILED DESCRIPTION OF THE PREFERRED EMBODIMENT

According to an embodiment of the present invention, there is provided a substrate exchanging mechanism that is configured into simple configurations and capable of increasing throughput.

Non-limiting, exemplary embodiments of the present invention will now be described with reference to the accompanying drawings. In the drawings, the same or corresponding reference marks are given to the same or corresponding members or components, and repetitive explanation is omitted.

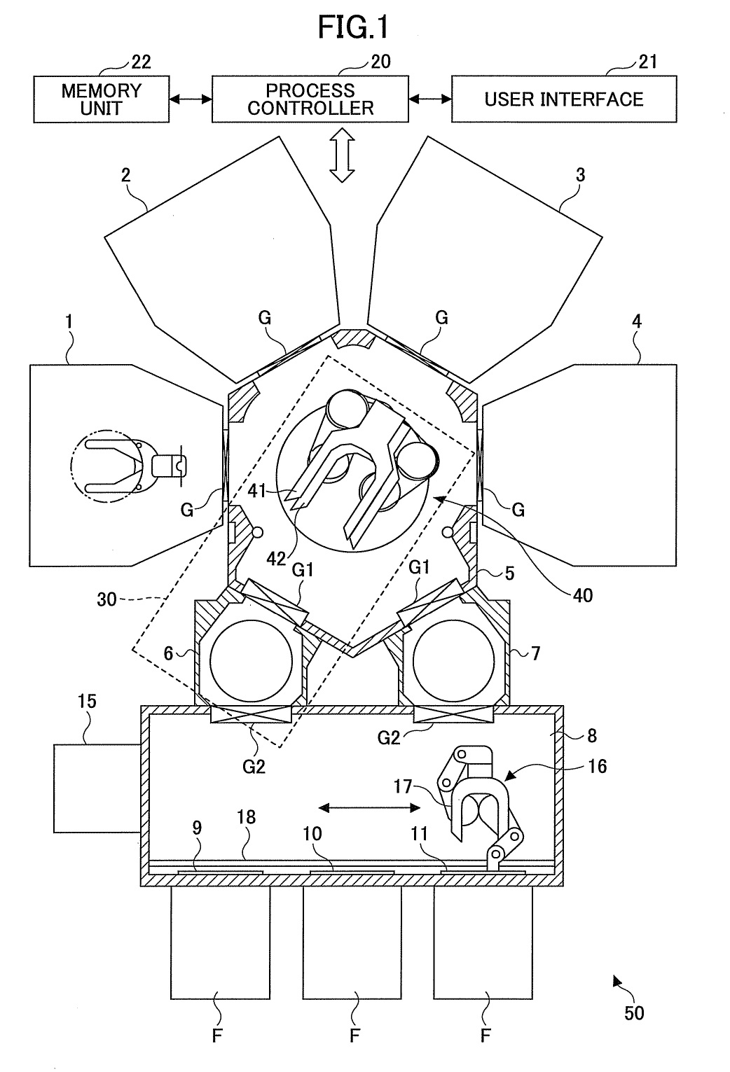

FIG. 1 is a plan view illustrating a substrate processing apparatus provided with a substrate exchanging mechanism according to an embodiment of the present invention.

A substrate processing apparatus 50 includes four process chambers 1 through 4 where high temperature processes such as film deposition are carried out. The process chambers 1 through 4 are arranged in corresponding four sides of a transfer chamber 5 having a hexagonal top view shape. Load lock chambers 6, 7 are arranged in the remaining two sides of the transfer chamber 5. A transfer-in/out chamber 8 is provided in the other side of the load lock chamber 6, 7 with respect to the transfer chamber 5. In addition, three ports 9, 10, 11 to which corresponding FOUPs (Front Opening Unified Pod) serving as a wafer carrier are attached are provided in the other side of the transfer-in/out chamber 8 with respect to the load lock chamber 6, 7. In the process chambers 1 through 4, the wafer is placed on process plates and undergoes predetermined processes such as the film deposition and etching.

The process chambers 1 through 4 are coupled with the corresponding sides of the transfer chamber 5 via corresponding gate valves G. The process chambers 1 through 4 are in pressure communication with the transfer chamber 5 when the corresponding gate valves G are opened, and shut out from the transfer chamber 5 when the corresponding gate valves G are closed. The load lock chambers 6, 7 are coupled at one side with the corresponding remaining sides of the transfer chamber 5 via first gate valves G1 and at the other side with the transfer-in/out chamber 8 via second gate valves G2. The load lock chambers 6, 7 are in pressure communication with the transfer chamber 5 when the corresponding first gate valves G1 are opened, and shut off from the transfer chamber 5 when the corresponding first gate valves G1 are closed. Additionally, the load lock chambers 6, 7 are in pressure communication with the transfer-in/out chamber 8 when the corresponding second gate valves G2 are opened, and shut off from the transfer-in/out chamber 8 when the corresponding gate valves G2 are closed.

A transfer apparatus 40 is provided in the transfer chamber 5 in order to transfer the wafer W to/from the process chambers 1 through 4 and the load lock chambers 6, 7. The transfer apparatus 40 is arranged in substantially the center of the transfer chamber 5. The transfer apparatus 40 has a first transferring member 41 and a second transferring member 42 that support the wafer W.

The ports 9, 10, 11 of the transfer-in/out chamber 8 are provided with corresponding shutters (not shown). When the FOUP F is directly attached to one of the ports 9, 10, 11 and thus the shutter of the port is opened, the FOUP F is in pressure communication with the transfer-in/out chamber 8. In such a manner, the inside of FOUP F cannot be exposed to an outer environment. An alignment chamber 15 is provided on one side surface of the transfer-in/out chamber 8, where the wafer W is aligned.

A transfer apparatus 16 is provided inside the transfer-in/out chamber 8 in order to transfer the wafer W to/from the FOUP F, the load lock chambers 6, 7, and the alignment chamber 15. The transfer apparatus 16 has a multiple joint arm structure and is movable on a rail 18 along a direction in which the ports 9, 10, 11 are arranged. Additionally, the transfer apparatus 16 has at the distal end a fork 17 on which the wafer W is placed when the wafer W is transferred.

The substrate processing apparatus 50 includes a process controller 20 composed of a microprocessor (computer), which is electrically connected to and controls each component or part of the substrate processing apparatus 50. In addition, the process controller 20 is connected to a user interface 21 including a keyboard with which an operator of the substrate processing apparatus 50 inputs operation commands and the like, a display that shows operational status of the substrate processing apparatus 50, and the like.

Moreover, the process controller 20 is connected to a memory unit 22 that stores control programs for executing various processes in the substrate processing apparatus 50, programs for executing processes in each component or part of the substrate processing apparatus 50, film deposition recipes for executing film deposition processes, transfer recipes for transferring the wafers W, purge recipes for controlling inner pressures of the load lock chambers 6, 7, and the like. Such programs and recipes are stored in a storage medium and loaded to the memory unit 22 from the storage medium. The storage medium may be a hard disk, a CD-ROM, a DVD, a flash memory, and the like. Alternatively, the programs and the recipes may be downloaded to the memory unit 22 through communication lines.

The programs and the recipes are read out from the memory unit 22 to the process controller 21 in response to an instruction from the user interface 21, and are executed, and thus the corresponding processes are carried out in the substrate processing apparatus 50 under control of the process controller 20. Additionally, the process controller 20 can control the inner pressure of the load lock chambers 6, 7 and an elevation of the wafers W during execution of the purge recipes, in order to reduce deformation or warpage of the wafers W.

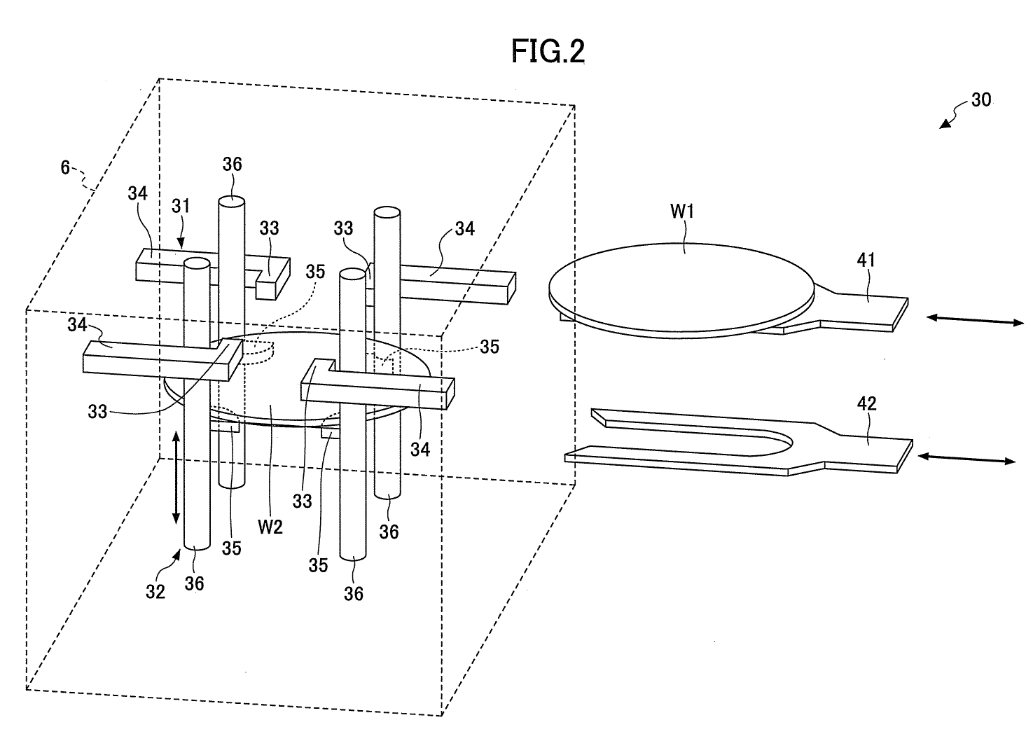

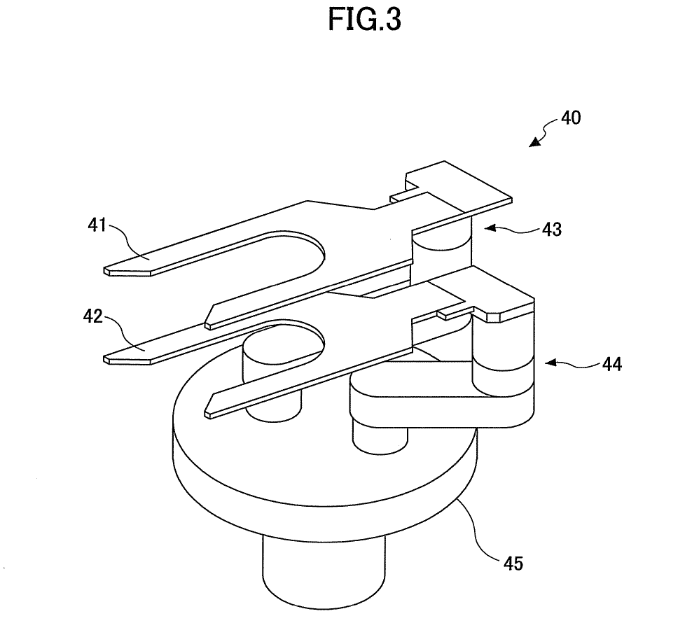

Referring to FIGS. 2 and 3, a substrate exchanging mechanism according to an embodiment of the present invention is explained.

As shown in FIG. 2, a substrate exchanging mechanism 30 according to this embodiment is configured with a first supporting member 31, a second supporting member 32, and the first and the second transferring members (forks) 41, 42 of the transfer apparatus 40, in order to exchange the wafers W between the load lock chamber 6 and the transfer chamber 5. While the following explanation is made taking an example of the load lock chamber 6, the same explanation is applicable to the load lock chamber 7 because the load lock chambers 6, 7 have the same configurations.

The first supporting member 31 is provided inside the load lock chamber 6 in order to support a wafer W1, which may be referred to as a first wafer W1. The first supporting member 31 includes four bar members 34 that have corresponding receiving portions 33 having an L-shape at their one ends. The other ends of the bar members 34 are fixedly attached on inner walls of the load lock chamber 6. While the first supporting member 31 is arranged substantially in corners of the load lock chamber 6 so that the bar members 34 do not interfere with the wafer W1 and the wafer transferring members 41, 42, the receiving portions 33 extend toward the center portion of the load lock chamber 6 so that the receiving portions 33 can support back surface edges of the wafer W1. Incidentally, the first supporting member 31 may include three or more bar members 34, as long as the wafer W1 can be supported by the first supporting member 31, although there are the four bar members 34 in the illustrated example.

The second supporting member 32 is also provided inside the load lock chamber 6 in order to support a wafer W2, which may be referred to as a second wafer W2. The second supporting member 32 includes four vertically movable pillar members 36 having circular cylinder shapes. The four pillar members 36 have corresponding wafer supporting portions 35 in their mid portions along a vertical direction. While the second supporting member 32 is also arranged substantially in the corners of the load lock chamber 6 so that the pillar members 36 do not interfere with the wafer W2 and the wafer transferring members 41, 42, the receiving portions 35 extend toward the center portion of the load lock chamber 6 so that the receiving portions 35 can support back surface edges of the wafer W2. It is noted that upper surfaces of the receiving portions 35 of the second supporting member 32 are positioned below upper surfaces of the receiving portions 33 of the first supporting member 31. Incidentally, the second supporting member 32 may include three or more bar members 36, as long as the wafer W2 can be supported by the second supporting member 32, although there are four bar members 36 in the illustrated example. In the following, the wafer receiving portion 33 and the wafer receiving portion 35 may be referred to as the first supporting member 31 and the second supporting member 32, respectively, for the sake of convenience.

On the other hand, the first transferring member (fork) 41 and the second transferring member (fork) 42 are provided in the transfer apparatus 40, and are accessible to the load lock chamber 6 in order to transfer the wafers W1, W2 to/from the load lock chamber 6. Specifically, the first transferring member 41 transfers the wafer W1 to/from the first supporting member 31 fixedly arranged in the load lock chamber 6, and the second transferring member 42 transfers the wafer W2 to/from the second supporting member 32 vertically movably arranged in the load lock chamber 6. The first transferring member 41 and the second transferring member 42 are arranged one above the other in order to access the load lock chamber 6 at different elevations from each other. Specifically, the second transferring member 42 is arranged below the first transferring member 41 in the illustrated example.

As shown in FIG. 3, the transfer apparatus 40 includes a first rotational/extensible portion 43 and a second rotational/extensible portion 44. The first transferring member 41 and the second transferring member 42 are attached at distal ends of the first rotational/extensible portion 43 and the second rotational/extensible portion 44, respectively. In addition, the first transferring member 41 and the second transferring member 42 are arranged one above the other at least when being extended, and can be directed toward the same direction. The first rotational/extensible portion 43 and the second rotational/extensible portion 44 are attached on a rotational portion 45 serving as a pedestal that is rotatable around its rotation center. The first transferring member 41 and the second transferring member 42 are moved in a vertical direction by a transferring member driving portion (not shown). The first rotational/extensible portion 43 and the second rotational/extensible portion 44 may be provided with corresponding transferring member driving portions that may move the first transferring member 41 and the second transferring member 42 in the vertical direction in unison or independently. Alternatively, the rotational portion 45 may be provided with one transferring member driving portion, so that the first transferring member 41 and the second transferring member 42 are moved in the vertical direction in unison via first rotational/extensible portion 43 and the second rotational/extensible portion 44, respectively.

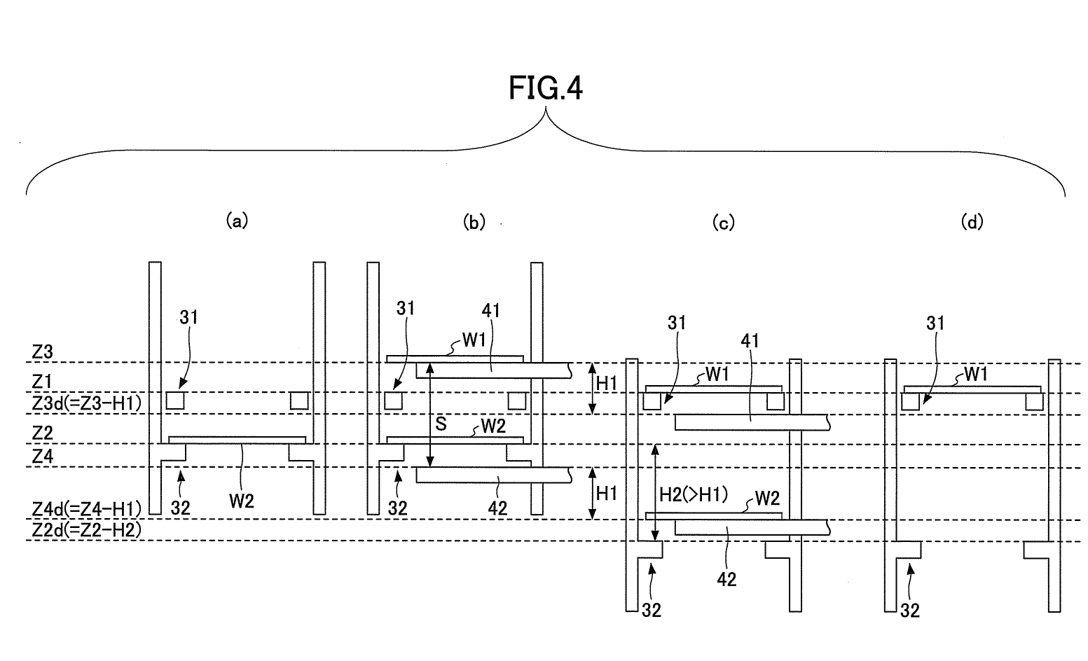

Next, referring to FIGS. 4 through 9, a substrate exchanging method according to embodiments of the present invention is explained where a processed wafer and an unprocessed wafer are exchanged between the load lock chamber 6 and the transfer apparatus 40.

### First Example

Referring to a subsection (a) of FIG. 4, a wafer W2, which has not yet been processed, is supported by the second supporting member 32 in the load lock chamber 6 (FIG. 2). While not shown in this subsection, a wafer W1, which has been processed, is supported by the first transferring member 41 of the transfer apparatus 40 at this time. Here, the first supporting member 31 of the load lock chamber 6 and the second transferring member 42 of the transfer apparatus 40 (FIG. 1) do not support any wafers.

Here, an upper surface (wafer supporting surface) of the first supporting member 31, which does not support a wafer, is positioned at a first position Z1 in a vertical direction; and an upper surface (wafer supporting surface) of the second supporting member 32, which supports the wafer W2, is positioned at a second position Z2 in the vertical direction. In this case, the first position Z1 is higher than the second position Z2, which is indicated as Z1>Z2 in the following explanation, for the sake of convenience.

Next, the first transferring member 41 supporting the wafer W1 and the second transferring member 42 supporting no wafer are moved into the load lock chamber 6, as shown in a subsection (b) of FIG. 4. In this case, a vertical gap S between the first transferring member 41 and the second transferring member 42 is greater than a vertical gap between the first supporting member 31 and the second supporting member 32. Here, an upper surface (wafer supporting surface) of the first transferring member 41 is positioned at a third position Z3 in the vertical direction, and an upper surface (wafer supporting surface) of the second transferring member 42 is positioned at a fourth position Z4 in the vertical direction. Because the first transferring member 41 is positioned above the second transferring member 42, the positional relationship between the first transferring member 41 and the second transferring member 42 is expressed as Z3>Z4. In addition, the distance S is expressed as S=Z3−Z4>0.

Next, the first transferring member 41 and the second transferring member 42 are moved downward in unison, and the second supporting member 32 is simultaneously moved downward, as shown in a subsection (c) of FIG. 4. In the illustrated example, a moving distance of the first and the second transferring members 41, 42 is a distance H1, and a moving distance of the second supporting member 32 is a distance H2 that is greater than H1 (H2>H1). With this, the second supporting member 32, the first transferring member 41 and the second transferring member 42 are positioned at positions Z2d (=Z2−H2), Z3d (=Z3−H1) and Z4d (=Z4−H1), respectively.

With such movements of the members 41, 42, and 32, the processed wafer W1 is transferred from the first transferring member 41 to the first supporting member 31, and the unprocessed wafer W2 is transferred from the second supporting member 32 to the second transferring member 42, as illustrated in the subsection (c) of FIG. 4. In order to realize such wafer transferring, it can be understood by comparing the subsections (b) and (c) of FIG. 4 that the following conditions need to be satisfied:

the first transferring member 41 is positioned above the first supporting member 31, namely Z3>Z1, before moving downward, and below the first supporting member 31, namely Z3d<Z1, after moving downward; and

the second transferring member 42 is positioned below the second supporting member 32, namely Z4<Z2, before moving downward, and above the second supporting member 32, namely Z4d>Z2d, after moving downward.

The above relationship of Z3d<Z1 is written as (Z3−H1)<Z1 because of Z3d=Z3−Z1.

Therefore, the distance H1 of the downward movement of the first and the second transferring members 41, 42 needs to be greater than a distance of Z3−Z1, which corresponds to a height difference between the first transferring member 41 and the first supporting member 31 at the time when the first transferring member 41 is moved into the load lock chamber 6.

In addition, the above relationship of Z4d>Z2d is written as Z4−H1>Z2−H2. Therefore, a relationship of H2>H1+(Z2−Z4) is obtained. Namely, the distance H2 of the downward movement of the second supporting member 32 needs to be greater than a summation of the distance H1 of the upward movement of the first and the second transferring members 41, 42 and a height difference between the second supporting member 32 and the second transferring member 42 at the time when the first and the second transferring members 41, 42 are moved into the load lock chamber 6.

Incidentally, the second supporting member 32 preferably moves faster than the first transferring member 41 and second transferring member 42. With this, a time period required for the second supporting member 32 to vertically move the first distance H1 is close to a time period required for the first transferring member 41 and the second transferring member 42 to vertically move the second distance H2, thereby reducing a time period for exchanging the wafers. More preferably, when a speed V2 of the second supporting member 32 is equal to V1×(H2/H1), where V1 is a speed of the first transferring member 41 and the second transferring member 42, the second supporting member 32 can move the second distance H2 at the same time period during which the first transferring member 41 and the second transferring member 42 move the first distance H1. Therefore, the time period for exchanging the wafers can be further reduced.

Incidentally, although the second supporting member 32 is moved downward while the first transferring member 41 and the second transferring member 42 are moved downward in unison in this example, the first transferring member 41, the second transferring member 42, and the second supporting member 32 may be moved in the following manner in other examples, as long as the above conditions are satisfied.

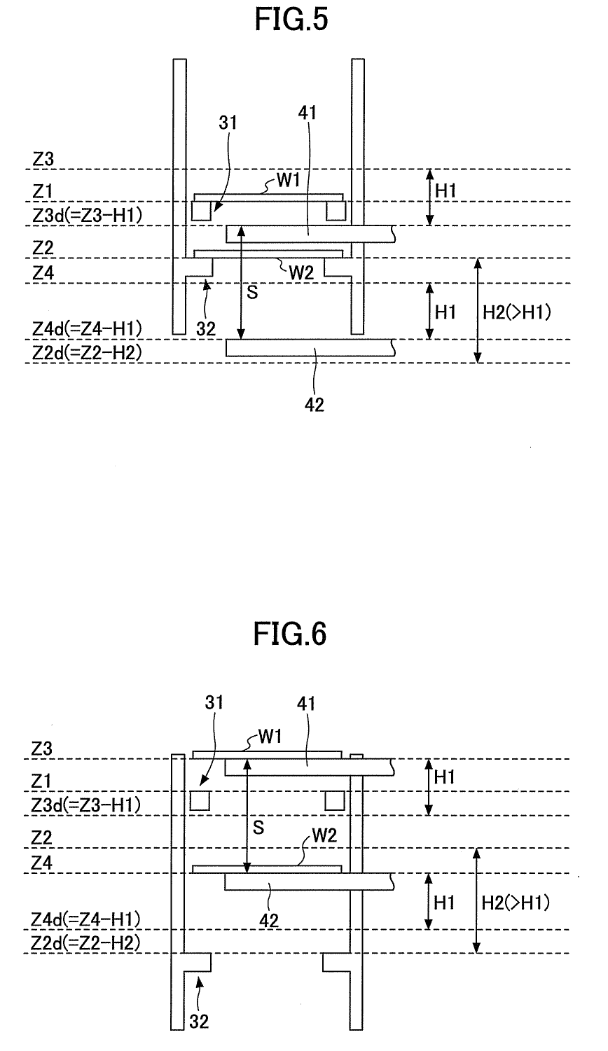

For example, after the first transferring member 41 and the second transferring member 42 are moved into the load lock chamber 6 (see the subsection (b) of FIG. 4), the first transferring member 41 and the second transferring member 42 are moved downward in unison by the distance H1, so that the wafer W1 is transferred from the first transferring member 41 to the first supporting member 31, as shown in FIG. 5. Subsequently, the second supporting member 32 is moved downward by the distance H2, so that the wafer W2 is transferred from the second supporting member 32 to the second transferring member 42 (see the subsection (c) of FIG. 4). In this case, it is necessary that the first transferring member 41 does not interfere with the wafer W2 supported by the second supporting member 32, in other words, a relationship H1<Z3−Z2 obtained from Z3d (=Z3−H1)>Z2 is satisfied when the first transferring member 41 and the second transferring member 42 are moved in unison.

In addition, after the first transferring member 41 and the second transferring member 42 are moved into the load lock chamber 6 (see the subsection (b) of FIG. 4), the second supporting member 32 is moved downward by the distance H2, so that the wafer W2 is transferred from the second supporting member 32 to the second transferring member 42, as shown in FIG. 6. Subsequently, the first transferring member 41 and the second transferring member 42 are moved downward in unison by the distance H1, so that the wafer W1 is transferred from the first transferring member 41 to the first supporting member 31 (see the subsection (c) of FIG. 4). In this case, the first transferring member 41 does not interfere with the wafer W2 supported by the second supporting member 32, which allows greater flexibility in designing the substrate exchanging mechanism 30.

Moreover, a time period when the first transferring member 41 and the second transferring member 42 are moved downward in unison may be partly overlapped with a time period when the second supporting member 32 is moved downward.

Furthermore, the first transferring member 41 and the second transferring member 42 may be independently moved downward, as long as the above conditions are satisfied.

Finally, the first transferring member 41 having no wafer and the second transferring member 42 having the wafer W2 are moved out from the load lock chamber 6. At this time, the first transferring member 41 is maintained at the position Z3d (=Z3−H1), and the second transferring member 42 is maintained at the position Z4d (=Z4−H1). In addition, the first supporting member 31 supporting the wafer W1 is positioned at Z1, and the second supporting member 32 supporting no wafer is positioned at Z2d (=Z2−H2), as shown in a subsection (d) of FIG. 4.

As explained above, the wafer W1 and the wafer W2 are exchanged between the load lock chamber 6 and the transfer apparatus 40, in this example.

### Second Example

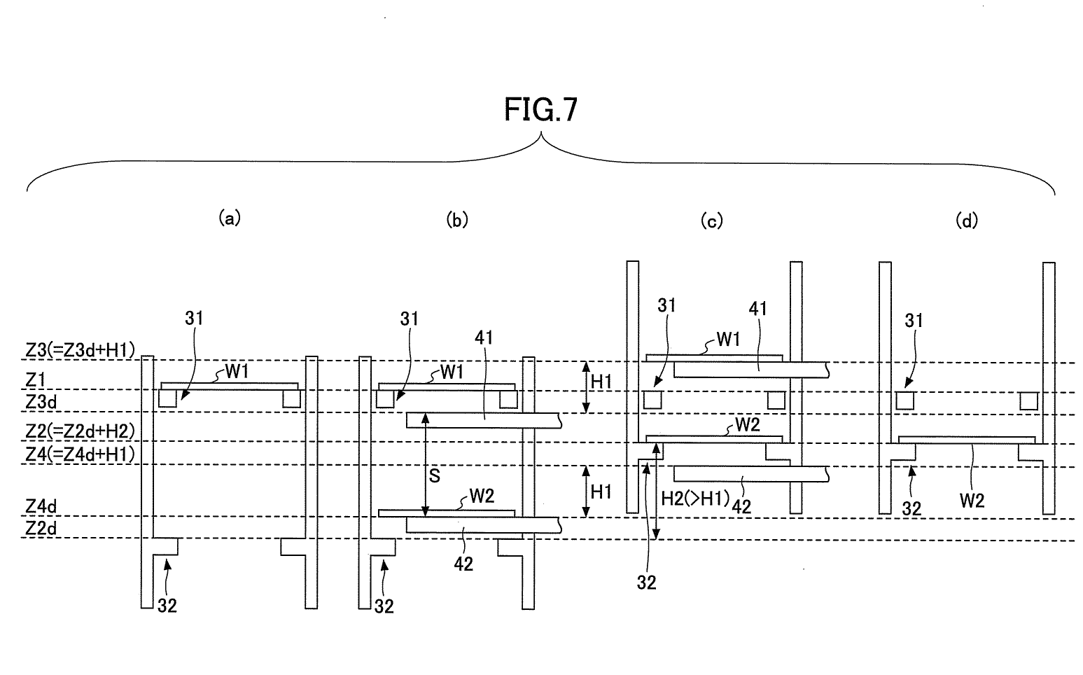

Next, a second example of the substrate exchange method according to the second embodiment of the present invention is explained with reference to FIG. 7.

Referring to a subsection (a) of FIG. 7, the first supporting member 31 is positioned at the first position Z1 and supports an unprocessed wafer W1, and the second supporting member 32 is positioned at the position Z2d, which is lower than the first position Z1, without supporting a wafer, in the load lock chamber 6. Note that the wafer W1 is unprocessed and supported by the first supporting member 31, which is different from the first example.

Next, as shown in a subsection (b) of FIG. 7, the first transferring member 41 supporting no wafer and the second transferring member 42 supporting a processed wafer W2 are moved into the load lock chamber 6. Note that the wafer W2 has been processed and is supported by the transferring member 42, which is different from the first example. At this time, the first transferring member 41 is positioned at a third position Z3d, which is lower than the position Z1 at which the first supporting member 31 is positioned, (Z3d<Z1) and the second transferring member 42 is positioned at a fourth position Z4d, which is higher than the second position Z2d at which the second supporting member 32 is positioned (Z4d>Z2d). Therefore, a vertical distance between the first supporting member 31 and the second supporting member 32 (Z1−Z2d) is greater than a vertical distance S between the first transferring member 41 and the second transferring member 42.

Next, as shown in a subsection (c) of FIG. 7, the first transferring member 41 and the second transferring member 42 are moved upward in unison by the distance H1, and the second supporting member 32 is simultaneously moved upward by the distance H2, which is greater than the distance H1 (H2>H1). With this, the unprocessed wafer W1 is transferred from the first supporting member 31 to the first transferring member 41, and the processed wafer W2 is transferred from the second transferring member 42 to the second supporting member 32. Here, the first transferring member 41 is positioned at Z3 (=Z3d+H1), the second transferring member 42 is positioned at Z4 (=Z4d+H1), and the second supporting member 32 is positioned at Z2 (=Z2d+H2).

By comparing the subsections (b) and (c) of FIG. 7, it is understood that:

the first transferring member 41 is positioned below the first supporting member 31, namely Z3d<Z1, before moving upward, and above the first supporting member 31, namely Z3>Z1, after moving upward; and

the second transferring member 42 is positioned above the second supporting member 32, namely Z4d>Z2d, before moving upward, and below the second supporting member 32, namely Z4<Z2, after moving upward.

From the above relationship Z3>Z1, a relationship H1>(Z1−Z3d) is obtained because Z3=Z3d+H1. Therefore, the distance H1 of the upward movement of the first and the second transferring members 41, 42 needs to be greater than a height difference between the first transferring member 41 (Z1) and the first supporting member 31 (Z3d) at the time when the first transferring member 41 is moved into the load lock chamber 6, which is the same as in the first example.

In addition, from the relationship Z4<Z2, a relationship H2>H1+(Z4d−Z2d) is obtained because Z2=Z2d+H2. Therefore, the distance H2 of the upward movement of the second supporting member 32 needs to be greater than a summation of the distance H1 of the upward movement of the first and the second transferring members 41, 42 and a height difference between the second supporting member 32 and the second transferring member 42 at the time when the first and the second transferring members 41, 42 are moved into the load lock chamber 6, which is the same as in the first example.

Incidentally, the procedures of the second example is opposite to the procedures of the first example, which is easily understood by comparing the subsections (a) through (d) of FIG. 7 with the subsections (d) through (a) of FIG. 4, respectively.

Even in the second example, the speed V2 of the second supporting member 32 moving upward is preferably greater than the speed V1 of the first and the second transferring members 41, 42 that are moved upward in unison, thereby reducing a time period required for exchanging the wafers W1, W2. More preferably, when the speed V2 is set to be equal to V1×(H2/H1), the second supporting member 32 can be moved upward by the distance H2 during the same period of time when the first and the second transferring members 41, 42 are moved upward in unison by the distance H1, thereby further reducing the time period required for exchanging the wafers W1, W2.

Incidentally, while the second supporting member 32 is moved upward when the first transferring member 41 and the second transferring member 42 are moved upward in unison in this example, the first transferring member 41, the second transferring member 42, and the second supporting member 32 may be moved in the following manner, in other examples.

Referring to FIG. 5 in comparison with the subsection (b) of FIG. 7, the second supporting member 32 is moved upward by the distance H2 from Z2d to Z2, while the first transferring member 41 and the second transferring member 42 remain at the positions Z3d and Z4d, respectively. As a result, the wafer W2 is transferred from the second transferring member 42 to the second supporting member 32. Next, when the first transferring member 41 and the second transferring member 42 are moved in unison upward by the distance H1, the wafer W1 is transferred from the first supporting member 31 to the first transferring member 41 (see the subsection (c) of FIG. 7). In this case, it is necessary that the wafer W2 supported by the second supporting member 32 does not interfere with the first transferring member 41, in other words, a relationship H2<Z3d−Z2d−α obtained from Z3d+α>Z2 (=Z2d+H2), where α is a thickness (height) of the first transferring member 41 is satisfied when the second supporting member 32 is moved upward.

Referring to FIG. 6 in comparison with the subsection (b) of FIG. 7, while the second supporting member 32 remains at the position Z2d the first transferring member 41 and the second transferring member 42 are moved in unison upward by the distance H1. As a result, the wafer W1 is transferred from the first supporting member 31 to the first transferring member 41. Next, when the second supporting member 32 is moved upward by the distance H2 from Z2d to Z2, the wafer W2 is transferred from the second transferring member 42 to the second supporting member 32 (see the subsection (c) of FIG. 7). In this case, the wafer W2 supported by the second supporting member 32 is less likely to interfere with the first transferring member 41, which allows greater flexibility in designing the substrate exchanging mechanism 30.

Moreover, a time period when the second supporting member 32 is moved upward may partly overlap with a time period when the first transferring member 41 and the second transferring member 42 are moved upward.

Furthermore, although the first transferring member 41 and second transferring member 42 are moved upward in unison in this example, the first transferring member 41 and the second transferring member 42 may be moved independently.

After the above procedures, the first transferring member 41 is positioned at Z3; the second transferring member 42 is positioned at Z4; the first supporting member 31 supporting no wafer is positioned at Z1; and the second supporting member 32 is positioned at Z2. Then, the first transferring member 41 supporting the unprocessed wafer W1 and the second transferring member 42 supporting no wafer are moved out from the load lock chamber 6 (see the subsection (d) of FIG. 7), and thus the substrate exchange method according to this example, which is carried out between the load lock chamber 6 and the transfer apparatus 40 (FIG. 1) is completed. Namely, the unprocessed wafer W1 originally supported by the first supporting member 31 is taken out from the load lock chamber 6 and the processed wafer W2 originally supported by the second transferring member 42 is now housed in the load lock chamber 6.

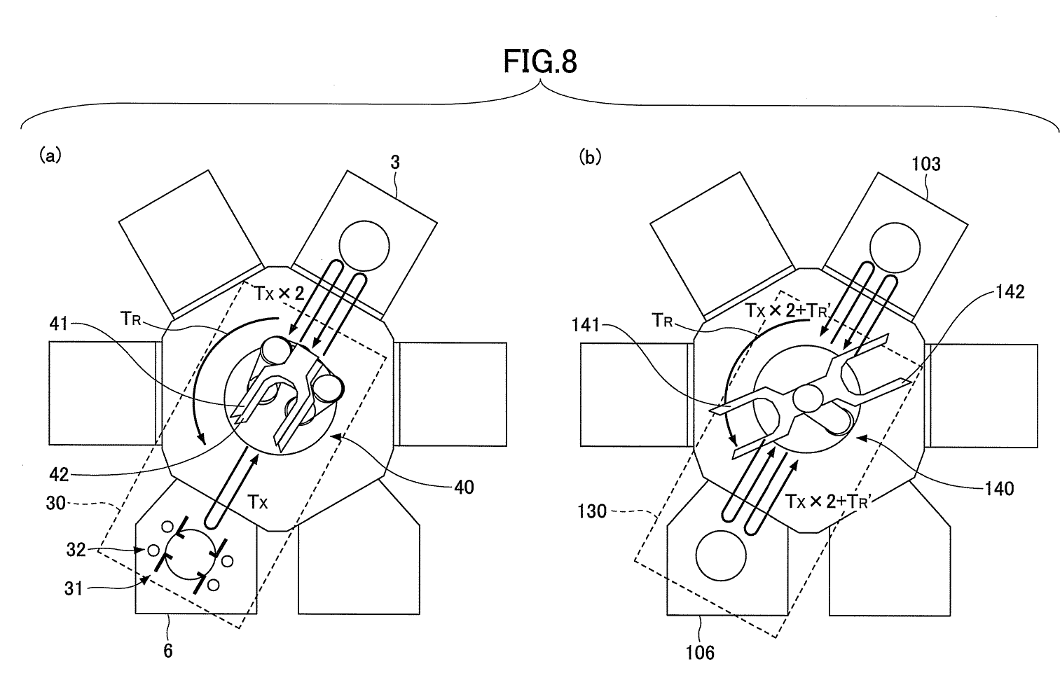

Next, effects (or advantages) of the substrate exchanging mechanism and the substrate exchange method according to the embodiment of the present invention are explained, with reference to FIG. 8.

A subsection (a) of FIG. 8 illustrates a substrate exchanging mechanism according to an embodiment of the present invention, and a subsection (b) of FIG. 8 illustrates a related art substrate exchanging mechanism for comparison.

In the following explanation, a time period required for the first and the second transferring members 41, 42 to move into the load lock chamber 6 and then to exchange the wafers with the first and the second supporting members 31, 32 is assumed to be TX; and a time period required for the first and the second transferring members 41, 42 to change their directions from/to the load lock chamber 6 to/from the process chamber 3 is assumed to be TR. In addition, a time period required for the first and the second transferring members 41, 42 to move into a process chamber 3 and then to exchange wafers with a susceptor provided in the process chamber 3 is also assumed to be TX.

Referring to the subsection (a) of FIG. 8, first, it takes TX×2 to exchange wafers between the transfer apparatus 40 and the process chamber 3. This is because the process chamber 3 is not provided with the first and the second supporting members 31, 32 in this example. Namely, the first transferring member 41 or the second transferring member 42 moves into the process chamber 3 in order to take a processed wafer from the susceptor and moves out from the process chamber 3 with the wafer, and then transfers an unprocessed wafer to the process chamber 3 to place the wafer on the susceptor and moves out the process chamber 3 without a wafer. Second, it takes TR for the first and the second transferring members 41, 42 to turn to the load lock chamber 6. Then, it takes TX for the first and the second transferring members 41, 42 to exchange wafers with the first and the second supporting members 31, 32 according to any one of the above substrate exchange methods. As a result, it takes TX×3+TR in total during the above procedures.

The related art substrate exchanging mechanism 130 is provided with a transfer apparatus 140 that has a first transferring member 141 and a second transferring member 142, as shown in the subsection (b) of FIG. 8. The first and the second transferring members 141, 142 are coupled back to back at a rotational shaft of the transfer apparatus 140, so that first and the second transferring members 141, 142 face opposite directions. According to such configurations, one of the first and the second transferring members 141, 142 is moved without carrying a wafer into a load lock chamber 106, takes a first wafer in the load lock chamber 106, and is moved out from the load lock chamber 106 with the first wafer, while the other one of the first and the second transferring members 141, 142 supports a second wafer. Then, the first and the second transferring members 141, 142 are rotated by 180° around the rotational shaft of the transfer apparatus 140, so that the one of the first and the second transferring members 141, 142 faces a process chamber 103 with the first wafer and the other one of the first and the second transferring members 141, 142 faces the load lock chamber 106. Then, the other one of the first and the second transferring members 141, 142 is moved into the load lock chamber 106 with the second wafer, leaves the second wafer in the load lock chamber 106, and is moved out without a wafer from the load lock chamber 106. Therefore, an additional time period TRd is required only when wafers are exchanged between the load lock chamber 106 and the transfer apparatus 140. In the same manner, the time period TRd is required when wafers are exchanged between the process chamber 103 and the transfer apparatus 140.

A time required for the first transferring member 141 or the second transferring member 142 to move into the load lock chamber 106 and then to leave or take a wafer in the load lock chamber 106 is assumed to be TX; and a time period required for the first transferring member 141 or the second transferring member 142 to change their directions from/to the load lock chamber 106 to/from the process chamber 103 is assumed to be TR. In addition, a time period required for the first and the second transferring members 141, 142 to move into a process chamber 103 and then to exchange wafers with a susceptor provided in the process chamber 103 is also assumed to be TX.

In this case, first, it takes TX×2+TRD to exchange wafers between the substrate process chamber 103 and the transfer apparatus 140. Second, it takes T2 for the transfer apparatus 140 to change its direction from the process chamber to the load lock chamber 106. Finally, it takes TX×2+TRd to exchange wafers between the load lock chamber and the transfer chamber 140. As a result, it takes TX×4+TRd×2+TR in total during the above procedures employing the related art substrate exchanging mechanism.

Therefore, a time period when the wafers are exchanged between the load lock chamber and the transfer apparatus can be shorter according to the substrate exchanging mechanism and substrate exchange method of an embodiment of the present invention than according to the related art substrate exchange method employing the substrate exchanging mechanism illustrated in the subsection (b) of FIG. 8, by TX+TRd. In addition, wafer throughput can be increased from 1/(TX×4+TRd×2+TR) to 1/(TX×3+TR), compared to the related art substrate exchange method.

### Modified Example

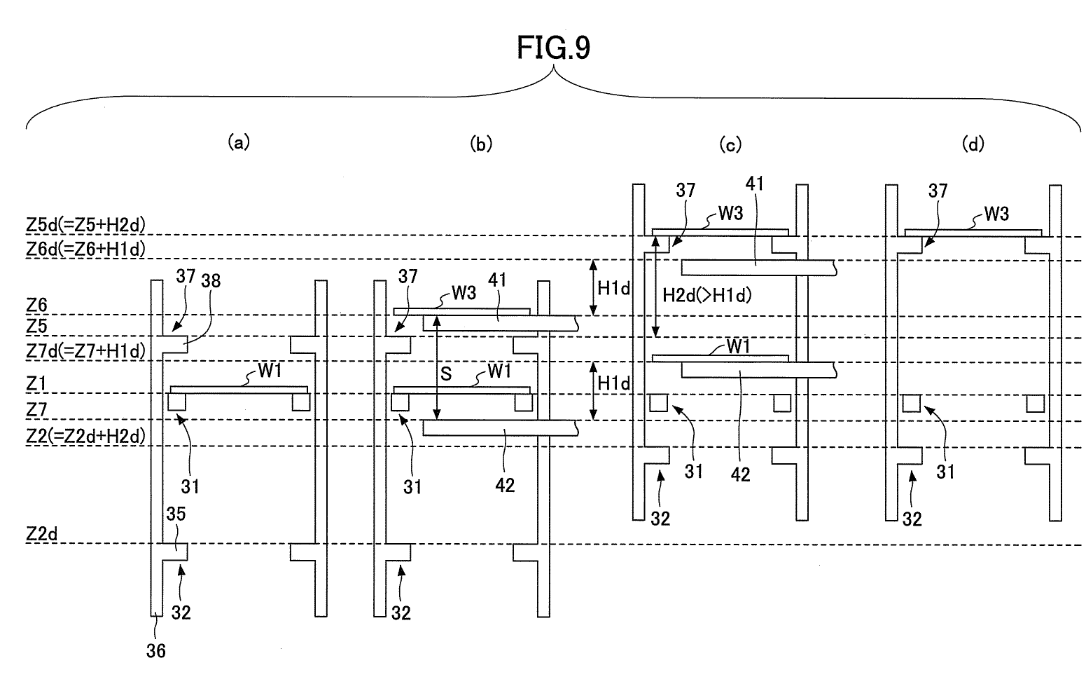

A modified example of the above embodiment of the present invention is explained with reference to FIGS. 9 through 11. Referring to a subsection (a) of FIG. 9, a wafer receiving portion of a third supporting member 37 is provided above the first supporting member 31 that is fixedly provided in the load lock chamber 6 (see FIG. 2). The wafer receiving portion of the third supporting member 37 is attached to the vertically movable pillar member 36 to which the wafer receiving portion 35 of the second supporting member 32 is attached in this example. Therefore, the third supporting member 37 and the second supporting member 32 are vertically movable in unison with each other with the second supporting member 32 therebetween. In addition, the third supporting member 37 can support a wafer in the same manner as the second supporting member 32. In the following, the wafer receiving portion 35 is referred to as the second supporting portion 32, and the wafer receiving portion 38 is referred to as the third supporting portion 37, for the sake of convenience.

In the subsection (a) of FIG. 9, the wafer W1, which has not yet been processed, is supported by the first supporting member 31. At this time, the second supporting member 32 and the third supporting member 37 do not support wafers. Note that the first, the second, and the third supporting members 31, 32, and 37 are positioned at Z1, Z2d, and Z5, respectively.

Referring to a subsection (b) of FIG. 9, the first transferring member 41 supporting a wafer W3 that has been processed and the second transferring member 42 supporting no wafer are moved into the load lock chamber 6. At this time, the first transferring member 41 is positioned at Z6 higher than Z5 at which the third supporting member 37 is positioned (i.e., Z6>Z5) and the second transferring member 42 is positioned at Z7 lower than Z1 at which the first supporting member 31 is positioned (i.e., Z7<Z1). In other words, the first supporting member 31 and the third supporting member 37 are arranged between the first transferring member 41 and the second transferring member 42.

Next, as shown in a subsection (c) of FIG. 9, the first transferring member 41 and the second transferring member 42 are moved upward in unison by the distance H1d, and the second supporting member 32 and the third supporting member 37 are moved upward in unison by the distance H2d that is greater than the distance H1d. With this, the wafer W1 is transferred from the first supporting member 31 to the first transferring member 41, and the wafer W3 is transferred from the first transferring member 41 to the third supporting member 37. At this time, the first transferring member 41, the second transferring member 42, the first supporting member 31, and the third supporting member 37 are positioned at Z6d (=Z6+H1d), Z7d (=Z7+H1d), Z1, and Z2 (=Z2d+H2d), respectively.

Comparing the subsections (b) and (c) of FIG. 9, the above wafer transferring is carried out when

the third supporting member 37 is positioned below the first transferring member 41, namely Z5<Z6, before moving upward, and above the first transferring member 41, namely Z5d>Z6d, after moving upward and

the second transferring member 42 is positioned below the first supporting member 31, namely Z7<Z1, before moving upward, and above the first supporting member 31, namely Z7d>Z1, after moving upward.

From the relationship Z7d>Z1, a relationship H1d>Z1−Z7 is obtained, and from the relationship Z5d>Z6d, a relationship H2d>H1d+(Z6−Z5) is obtained. Therefore, the distance H1d of the upward movement of the first transferring member 41 and the second transferring member 42 needs to be greater than a height difference between the first supporting member 31 and the second transferring member 42 at the time when the first transferring member 41 and the second transferring member 42 are moved into the load lock chamber 6. In addition, the distance H2d needs to be greater than a summation of the distance H1d and a height difference between the first transferring member 41 and the third supporting member 37 at the time when the first transferring member 41 and the second transferring member 42 are moved into the load lock chamber 6.

The first transferring member 41, the second transferring member 42, the second supporting member 32, and the third supporting member 37 are moved in the vertical direction in order to satisfy the above relationships, so that the processed wafer W3 is transferred from the first transferring member 41 to the third supporting member 37, and the unprocessed wafer W1 is transferred from the first supporting member 31 to the second transferring member 42.

In this modified example, the second supporting member 32 and the third supporting member 37 are preferably moved upward faster at a speed V2d than the first transferring member 41 and the second transferring member 42 moving at a speed V1d, thereby reducing a time period for exchanging the wafers. More preferably, the speed V2d is equal to V1d×(H2d/H1d). With this, the second supporting member 32 and the third supporting member 37 can move the distance H2 during the same time period when the first transferring member 41 and the second transferring member 42 move the distance H1, thereby further reducing a time period for exchanging the wafers.

Incidentally, although the first and the second transferring members 41, 42 are moved upward in unison, and the second and the third supporting members 32, 37 are moved upward in unison, these members 41, 42, 32, 37 may be moved in the following manners in other examples, as long as the above conditions are satisfied.

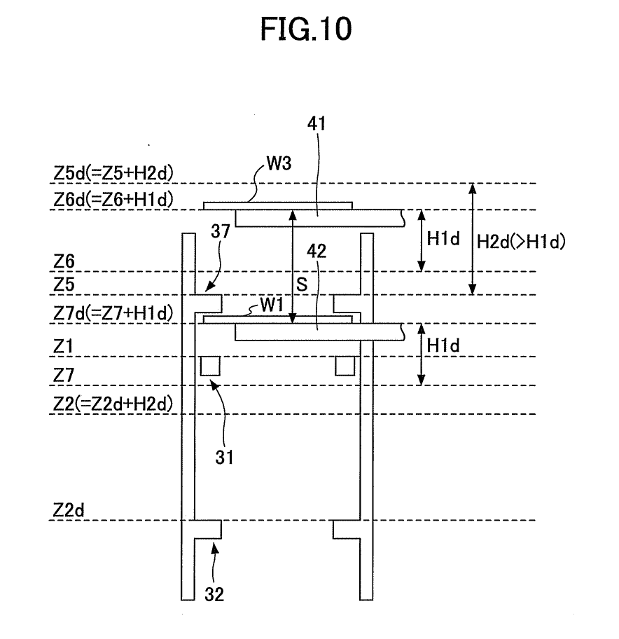

Referring to FIG. 10 in comparison with the subsection (b) of FIG. 9, the first transferring member and the second transferring member 42 are moved upward in unison by the distance H1d, while the second supporting member 32 and the third supporting member 37 remain stationary. As a result, the wafer W1 is transferred from the first supporting member 31 to the second transferring member 42. Next, when the second supporting member 32 and the third supporting member 37 are moved upward in unison by the distance H2d, the wafer W3 is transferred from the first transferring member 41 to the third supporting member 37 (see the subsection (c) of FIG. 9). In this case, it is necessary that the wafer W3 supported by the second transferring member 42 does not interfere with the third transferring member 37.

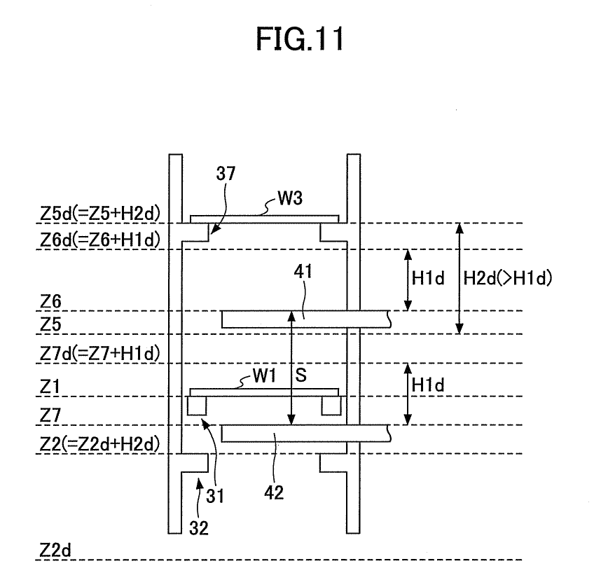

Referring to FIG. 11 in comparison with the subsection (b) of FIG. 9, the second supporting member 32 and the third supporting member 37 are moved upward in unison by the distance H2d, while the first transferring member 41 and the second transferring member 42 remain stationary. As a result, the wafer W3 is transferred from the first transferring member 41 to the third transferring member 37. Next, when the first transferring member 41 and the second transferring member 42 are moved upward in unison by the distance H1d, the wafer W1 is transferred from the first supporting member 31 to the second transferring member (see the subsection (c) of FIG. 9). In this case, the first transferring member 41 does not interfere with the wafer W3 supported by the third supporting member 37, which allows greater flexibility in designing the substrate exchanging mechanism 30.

Moreover, a time period when the first transferring member 41 and the second transferring member 42 are moved upward may partly overlap with a time period when the second supporting member 32 and the third supporting member 37 are moved upward.

Furthermore, although the first transferring member 41 and second transferring member 42 are moved upward in unison in this embodiment, the first transferring member 41 and the second transferring member 42 may be moved independently.

After the above procedures, the first transferring member 41 is positioned at Z6d (=Z6+H1d); the second transferring member 42 is positioned at Z4; the first supporting member 31 supporting no wafer is positioned at Z7d (=Z7+H1d); the second supporting member 32 is positioned at Z2 (=Z2d+H2d); and the third supporting member 37 is positioned at Z5d (=Z5+H2d). Then, the first transferring member 41 supporting no wafer and the second transferring member 42 supporting the wafer W1 are moved out from the load lock chamber 6 (see the subsection (d) of FIG. 7), and thus the substrate exchange method according to this modified example, which is carried out between the load lock chamber 6 and the transfer apparatus 40 (FIG. 1) is completed. Namely, the unprocessed wafer W1 originally supported by the first supporting member 31 is taken out from the load lock chamber 6 and the processed wafer W3 originally supported by the first transferring member 41 is now housed in the load lock chamber 6.

According to the substrate exchanging mechanism according to this modified example, the first example of the substrate exchange method explained with reference to FIG. 4 and the second example of substrate exchange method explained with reference to FIG. 7 can be carried out (see FIG. 4) by employing the stationary first supporting member 31 and the vertically movable second supporting member 32 that are provided in the load lock chamber 6, in addition to the modified example. For example, when an unprocessed wafer is supported by the first supporting member 31 for some reasons after the first example is carried out, the wafers can be exchanged between the load lock chamber 6 and the transfer apparatus 40 by carrying out the modified example explained with reference to FIG. 9

While the present invention has been described in reference to the foregoing embodiments, the present invention is not limited to the disclosed embodiments, but may be modified or altered within the scope of the accompanying claims.

What is claimed is:

1. A substrate exchanging mechanism that exchanges substrates between a load lock chamber and a transfer apparatus of a substrate process apparatus, the substrate exchanging mechanism comprising:
a first supporting member fixedly provided in the load lock chamber and configured to be capable of supporting a first substrate;
a second supporting member, capable of vertical movement, in the load lock chamber and configured to be capable of supporting a second substrate; and
a first transferring member and a second transferring member that are provided in the transfer apparatus in order to transfer a substrate, and configured to be movable into the load lock chamber and vertically movable,
wherein the first supporting member and the first transferring member are configured so that the first transferring member is moved in a first direction of upward and downward directions in the load lock chamber, thereby transferring the first substrate between the first supporting member and the first transferring member, and
wherein the second supporting member and the second transferring member are configured to move in the first direction in at least an overlapping period of time so that vertical positions of the first supporting member and the first transferring member are reversed, thereby transferring the second substrate between the first supporting member and the first transferring member.

2. The substrate exchanging mechanism of claim 1, wherein the first and the second transferring members are moved in unison in the first direction.

3. The substrate exchanging mechanism of claim 2, wherein a relationship H2>H1+D is satisfied, where H2 is a moving distance of the second supporting member in the first direction, H1 is a moving distance of the first and the second transferring members in the first direction, and D is a height difference between a substrate supporting portion of the second supporting member and a substrate supporting portion of the second transferring member before moving in the first direction.

4. The substrate exchanging mechanism of claim 2, wherein the second supporting member is configured to move faster than the first and the second transferring members in the first direction.

5. The substrate exchanging mechanism of claim 4, wherein a relationship V2=V1×(H2/H1) is satisfied, where V2 is a speed of the second supporting member, V1 is a speed of the first transferring member and the second transferring member, H2 is a moving distance of the second supporting member in the first direction, and H1 is a moving distance of the first and the second transferring members in the first direction.

6. The substrate exchanging mechanism of claim 1, further comprising an additional second supporting member provided in the load lock chamber.

7. A substrate exchange method carried out with a substrate exchanging mechanism recited in claim 1, the method comprising steps of:
moving the first transferring member that has been moved into the load lock chamber in the first direction of upward and downward directions, thereby transferring the first substrate between the first transferring member and the first supporting member;
moving the second transferring member that has been moved into the load lock chamber in the first direction; and
moving the second supporting member in the first direction in at least the overlapping period of time with the second transferring member so that vertical positions of the second supporting member and the second transferring member are reversed, thereby transferring the second substrate between the second transferring member and the second supporting member.

8. The substrate exchange method of claim 7, wherein the first and the second transferring members are moved in unison in the first direction.

9. The substrate exchange method of claim 8, wherein the steps of moving the first transferring member, moving the second transferring member, and moving the second supporting member are carried out so that a relationship H2>H1+D is satisfied, where H2 is a moving distance of the second supporting member in the first direction, H1 is a moving distance of the first and the second transferring members in the first direction; and D is a height difference between a substrate supporting portion of the second supporting member and a substrate supporting portion of the second transferring member before moving in the first direction.

10. The substrate exchange method of claim 9, wherein the second supporting member is moved faster than the first and the second transferring members in the first direction, in the step of moving the second supporting member.

11. The substrate exchange method of claim 10, wherein a relationship V2=V1×(H2/H1) is satisfied, where V2 is a speed of the second supporting member, V1 is a speed of the first transferring member and the second transferring member, H2 is a moving distance of the second supporting member in the first direction, and H1 is a moving distance of the first and the second transferring members in the first direction.
